(19) United States
(12) Patent Application Publication
(10) Pub. No.: US 2007/0181422 A1
(43) Pub. Date: Aug. 9, 2007

(54) Sputtering apparatus and anti-adhesion plate therefor

(75) Inventor: Naoto Nishimura, Fujimi-machi (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 11/703,374

(22) Filed: Feb. 7, 2007

(30) Foreign Application Priority Data
Feb. 8, 2006 (JP) 2006-030609

(51) Int. Cl. C23C 14/00

(52) U.S. Cl. 204/298.02

(57) ABSTRACT

A sputtering apparatus includes a first cover surrounding a periphery of a target, having a first opening through which sputtered particles from the target are emitted, and being made of a conductive material; a second cover having a second opening through which the sputtered particles from the target are adhered onto a substrate, the second cover being made of a conductive material; an O-ring placed between the first cover and the second cover to allow the first opening and the second opening to communicate with each other via a hollow center portionof the O-ring, the O-ring being made of an insulating material; and a third cover placed via an insulating material over a face of at least one of the first cover and the second cover facing the O-ring, the third cover being made of a conductive material.

### BACKGROUND

1. Technical Field

The present invention relates to sputtering apparatuses and anti-adhesion plates therefor.

2. Related Art

Sputtering has been widely employed in forming thin films in semiconductor and electronic devices. In a general sputtering apparatus, a target is placed in a vacuum chamber, and a substrate is placed facing the target. Application of a predetermined voltage on the target generates plasma on the target, from which sputtered particles are scattered and deposited on the substrate. In this manner, a thin film made of the sputtered particles is formed on the substrate.

To prevent the sputtered particles from adhering to a substrate holder in which the substrate is mounted, an anti-adhesion plate is used. The anti-adhesion plate is formed and placed so that the sputtered particles will not be deposited on the surface of the substrate holder (for example, see JP-A-2004-339581).

A so-called abnormal discharge may be generated between the target and the anti-adhesion plate or a frame of the target. Since the generation of the abnormal discharge may cause an unpleasant change in electric field or dusting in the sputtering apparatus, the thin film thus formed may be of a poor quality.

Therefore, the anti-adhesion plate may be insulated by disposing an O-ring made of an insulating material between a frame surrounding the target and a frame surrounding the substrate. As a result, no electric current channel is formed in the frame of the target or the anti-adhesion plate, thereby preventing generation of an abnormal discharge.

However, the longer the sputtering apparatus is used, the more the O-ring becomes worn out, resulting in a reduction in insulation performance. In such a state, electrical conduction may be established with the grounded frame of the substrate, thereby generating an abnormal discharge.

### SUMMARY

An advantage of some aspects of the invention is that it provides a sputtering apparatus for preventing an abnormal discharge therein.

A sputtering apparatus according to an aspect of the invention includes a first cover surrounding a periphery of a target, having a first opening through which sputtered particles from the target are emitted, and being made of a conductive material; a second cover having a second opening through which the sputtered particles from the target are adhered onto a substrate, the second cover being made of a conductive material; an O-ring placed between the first cover and the second cover to allow the first opening and the second opening to communicate with each other via a hollow center portionof the O-ring, the O-ring being made of an insulating material; and a third cover placed via an insulating material over a face of at least one of the first cover and the second cover facing the O-ring, the third cover being made of a conductive material.

With the above-described structure, a sputtering apparatus for preventing an abnormal discharge therein is provided.

It is preferable that the third cover have a first extension extending from the face to a corresponding inner periphery of the first opening or the second opening, the first extension being disposed via the insulating material.

With the above-described structure, the inner periphery of the opening is also insulated. Even when the O-ring becomes worn out, the insulating material prevents generation of an abnormal discharge between the end face of the opening of the cover and the target.

It is preferable that the third cover have a second extension extending from the face to a corresponding outer periphery of the first cover or the second cover, the second extension being disposed via the insulating material.

With the above-described structure, the outer periphery of the cover is also insulated. Even when the O-ring becomes worn out, the insulating material prevents generation of an abnormal discharge between the outer periphery of the cover and the target.

It is preferable that the third cover be an anti-adhesion plate having an irregular surface.

With the above-described structure, the cover functions as an anti-adhesion plate.

A sputtering-apparatus anti-adhesion plate according to another aspect of the invention is a substrate cover having an opening through which sputtered particles from a target are adhered onto a substrate. The anti-adhesion plate includes a plate member having the opening and being made of a conductive material. An insulating material is disposed on a first surface of the plate member, and a second surface of the plate member is an irregular surface having an anti-adhesion function.

With the above-described structure, a sputtering-apparatus anti-adhesion plate for preventing an abnormal discharge in a sputtering apparatus is provided.

### BRIEF DESCRIPTION OF THE DRAWINGS

The invention will be described with reference to the accompanying drawings, wherein like numbers reference like elements.

FIG. 1 is a schematic diagram for describing the structure of a sputtering apparatus according to an embodiment.

FIG. 2 is a partial sectional view of two covers.

FIG. 3 is an exploded perspective view of main components of the sputtering apparatus.

FIG. 4 is a schematic diagram for describing the structure of a sputtering apparatus according to a modification of the embodiment.

FIG. 5 is a partial sectional view of two covers according to the modification of the embodiment.

### DESCRIPTION OF EXEMPLARY EMBODIMENTS

An embodiment of the invention will be described with reference to the drawings.

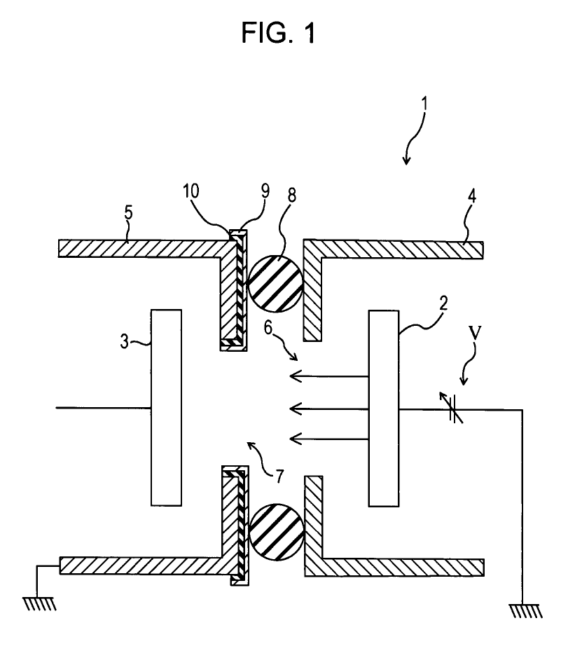

Referring to FIG. 1, the structure of a sputtering apparatus according to an embodiment will be described. FIG. 1 is a schematic diagram for describing the structure of a sputtering apparatus according to an embodiment.

In FIG. 1, a sputtering apparatus 1 has a vacuum chamber in which a target 2 and a substrate 3 are placed facing each other. Predetermined electrical power with a predetermined voltage waveform is supplied from a power source V to the target 2. Application of a predetermined voltage to the target 2 generates plasma on the surface of the target 2, from which sputtered particles are emitted. The sputtered particles emitted from the target 2 are adhered onto the substrate 3, thereby forming a thin film. The substrate 3 on which the thin film is formed is a substrate for a semiconductor device, such as a liquid crystal device. The thin film is, for example, a thin film for an electrode on the substrate of the liquid crystal device. The substrate 3 is maintained at a predetermined potential with respect to a ground potential.

The sputtering apparatus 1 includes a cover 4 serving as a frame formed to surround the periphery of the target 2 and a cover 5 serving as a frame formed to surround the substrate 3. The cover 5 constitutes a shield frame. The covers 4 and 5 are made of a conductive material, such as a stainless steel. The covers 4 and 5 have openings 6 and 7, respectively. When a sputtering treatment is performed, sputtered particles emitted from the target 2 pass through the openings 6 and 7. In particular, the opening 7 is an opening for allowing the sputtered particles to be adhered to a predetermined region on the substrate 3. In this case, the opening 7 toward the substrate 3 has a substantially circular shape along the planar shape of the substrate 3. The opening 6 toward the target 2 has an aperture area larger than that of the opening 7 and has a rectangular shape in this case.

The covers 4 and 5 are arranged with an O-ring 8 disposed therebetween, which is made of an insulating material such as a rubber material or the like so that the covers 4 and 5 are not electrically connected with each other when a sputtering treatment is performed. The O-ring 8 has a ring shape, and the center of the ring is a hollow center portionserving as a hole. The O-ring 8 is placed between the covers 4 and 5. The openings 6 and 7 communicate with each other via the hollow center portionof the O-ring 8. The sputtered particles emitted from the target 2 go through this communicating part and reach the substrate 3.

A cover 9 made of a conductive material is disposed on a face 5a of the cover 5 facing the cover 4 via an insulating material 10. The insulating material 10 is, for example, Teflon®. When a sputtering treatment is performed, the covers 4 and 5 are arranged with the O-ring 8, the cover 9, and the insulating material 10 disposed therebetween.

The cover 4 is not grounded and is electrically floating with respect to the target 2. The substrate 3 is at a predetermined potential with respect to the target 2. The cover 9 is also electrically floating.

The covers 4, 5, and 9 are made of a conductive material, such as a stainless used steel (SUS) or the like. The cover 9 has a function as an anti-adhesion plate. The anti-adhesion plate has a finely irregular surface so that, even when the sputtered particles are adhered thereto, the adhered sputtered particles do not come off. The surface of the stainless cover 9 is coated with copper (Cu) or the like by thermal spraying to form an irregular surface. This adds an anti-adhesion function to the cover 9 so as to serve as the anti-adhesion plate.

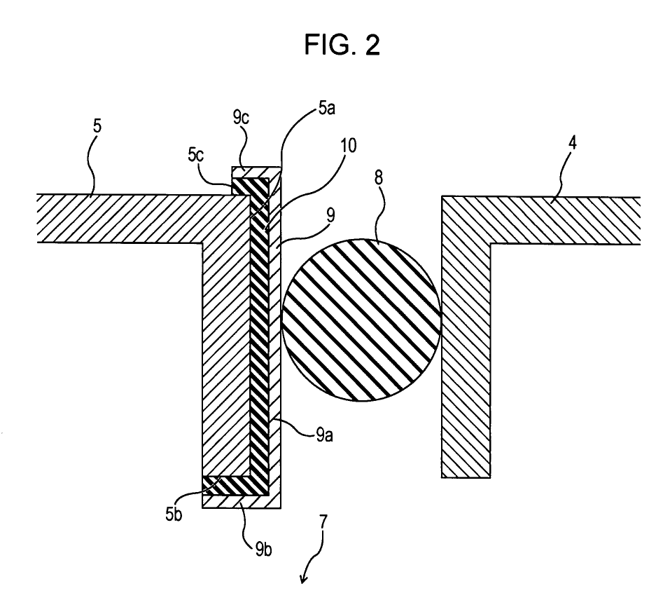

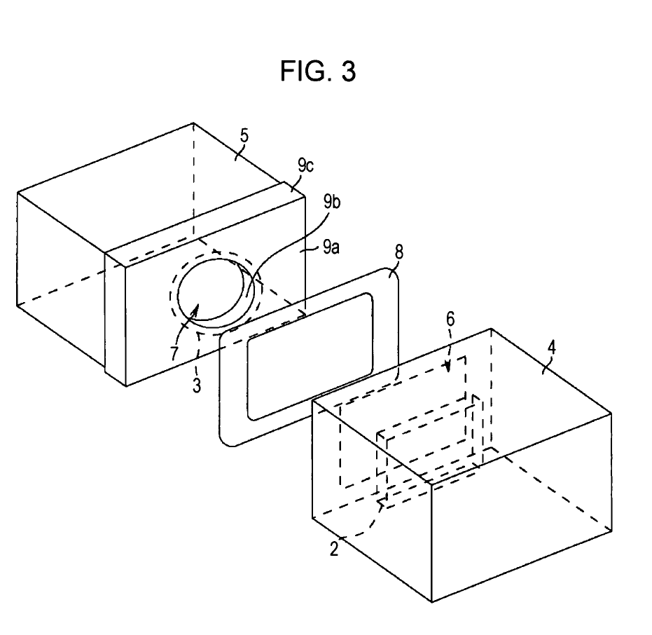

Next, the structure of the sputtering apparatus 1 will be described in more detail. FIG. 2 is a partial sectional view of the covers 4 and 5. FIG. 3 is an exploded perspective view of main components of the sputtering apparatus 1.

The ring-shaped cover 9, which is a plate member, is disposed via the insulating material 10 on the planar face 5a of the cover 5 facing the cover 4. Even when the O-ring 8 becomes worn out, the insulating material 10 prevents generation of an abnormal discharge, i.e., micro-arching, between the cover 5 and the target 2.

The insulating material 10 is also disposed on an inner periphery 5b of the opening 7 of the cover 5. The cover 9 has an extension 9b bending from a ring-shaped planar portion 9a firmly attached to the face 5a toward the inner periphery 5b of the opening 7 and extending along the inner periphery 5b.

The insulating material 10 is also disposed on an outer periphery 5c of the cover 5. The cover 9 has an extension 9c bending from the ring-shaped planar portion 9a firmly attached to the face 5a toward the outer periphery 5c and extending along the outer periphery 5c.

The cover 9 is fixed by a fixture such as a screw to the cover 5. By loosening the screw, the cover 9 can be replaced.

Next, the case in which the O-ring 8 becomes worn out will be described. In a known sputtering apparatus, the O-ring 8 becomes worn out and an abnormal discharge is generated when the covers 4 and 5 come into contact with each other or do not come into contact with each other, but become very close to each other, and, as a result, an electrical current channel is formed, through which an electrical current flows from the target 2 to the grounded cover 5 via the cover 4.

In contrast, according to the embodiment, even when the O-ring 8 becomes worn out, the cover 9 and the cover 5 are insulated from each other by the insulating material 10. Thus, no electrical current channel is formed, through which an electrical current flows from the target 2 to the grounded cover 5. According to the sputtering apparatus 1, an abnormal discharge can be prevented, and a high-quality thin film can be formed.

In particular, the cover 9 has the extension 9b extending to the inner periphery 5b of the opening 7 of the cover 5 and the extension 9c extending to the outer periphery 5c of the cover 5. The extensions 9b and 9c are insulated from the cover 5 by the insulating material 10. That is, besides the face 5a of the cover 5 facing the cover 4, the cover 9 has the additional extensions 9b and 9c so that no abnormal discharge is generated between the target 2 and the inner periphery 5b serving as an end face of the opening 7 of the cover 5 and between the target 2 and the outer periphery 5c of the cover 5. Since the inner periphery 5b of the opening 7 of the cover 5 is also insulated, even when the O-ring 8 becomes worn out, the insulating material 10 can prevent generation of an abnormal discharge between the end face of the opening 7 of the cover 5 and the target 2. In addition, since the outer periphery 5c of the cover 5 is also insulated, even when the O-ring 8 becomes worn out, the insulating material 10 can prevent generation of an abnormal discharge between the outer periphery 5c of the cover 5 and the target 2.

According to the sputtering apparatus 1 of the embodiment, an abnormal discharge can be reliably prevented, thereby forming a high-quality thin film.

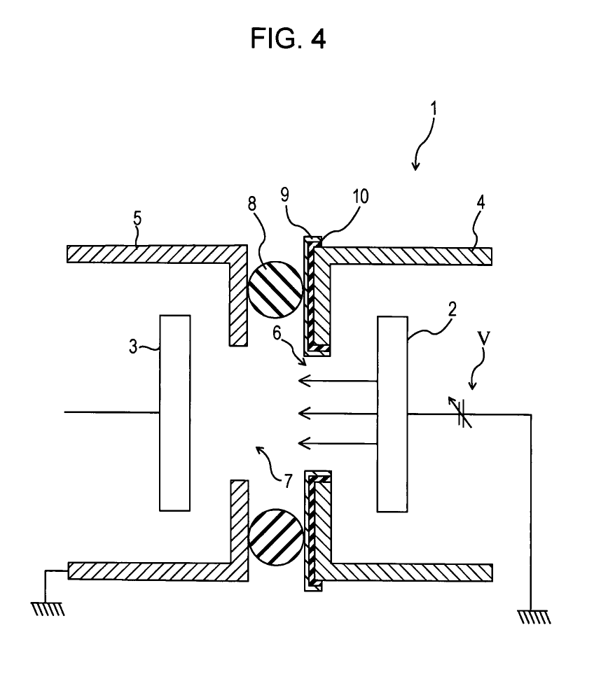

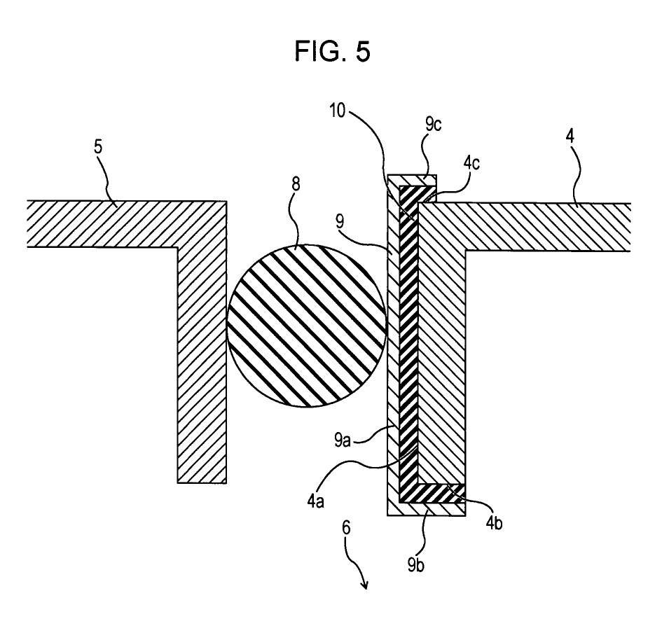

According to the embodiment, the cover 9 is placed over the cover 5 surrounding the substrate 3 on which a thin film is formed. Alternatively, as a modification, the cover 9 may be placed over the cover 4 surrounding the target 2. FIG. 4 is a schematic diagram for describing the structure of a sputtering apparatus in which the cover 9 is placed over the cover 4 surrounding the target 2. FIG. 5 is a partial sectional view of the covers 4 and 5 in which the cover 9 is placed over the cover 4 surrounding the target 2. In FIGS. 4 and 5, the cover 9 is placed, via an insulating material, over a face 4a of the cover 4 facing the cover 5. Thus, no electrical current channel through which an electrical current flows from the target 2 to the grounded cover 5 is formed.

As in FIGS. 1 and 2, the cover 9 has the extension 9b extending to an inner periphery 4b of the opening 6 of the cover 4 and the extension 9c extending to an outer periphery 4c of the cover 4. The extensions 9b and 9c are insulated from the cover 4 by the insulating material 10. In addition, the cover 9 has the extension 9b extending from the ring-shaped planar portion 9a firmly attached to the face 4a toward the inner periphery 4b of the opening 6 and extending along the inner periphery 4b.

Specifically, the ring-shaped cover 9, which is a plate member, is disposed via the insulating material 10 on the planar face 4a of the cover 4 facing the cover 5. Even when the O-ring 8 becomes worn out, the insulating material 10 prevents generation of an abnormal discharge between the cover 5 and the target 2.

The insulating material 10 is also disposed on the inner periphery 4b of the opening 6 of the cover 4. The cover 9 has the extension 9b bending from the ring-shaped planar portion 9a firmly attached to the face 4a toward the inner periphery 4b of the opening 6 and extending along the inner periphery 4b. In addition, the insulating material 10 is also disposed on the outer periphery 4c of the cover 4. The cover 9 has the extension 9c bending from the ring-shaped planar portion 9a firmly attached to the face 4a toward the outer periphery 4c and extending along the outer periphery 4c.

Since the inner periphery 4b of the opening 6 of the cover 4 is additionally insulated, even when the O-ring 8 becomes worn out, the insulating material 10 can prevent generation of an abnormal discharge between the end face of the opening 6 of the cover 4 and the cover 5. Since the outer periphery 4c of the cover 4 is additionally insulated, even when the O-ring 8 becomes worn out, the insulating material 10 can prevent generation of an abnormal discharge between the outer periphery 4c of the cover 4 and the cover 5.

As has been described above, according to the sputtering apparatus of the embodiment, generation of an abnormal discharge can be reliably prevented. Thus, no unpleasant change in electric field or dusting is caused in the sputtering apparatus. As a result, the quality of a thin film formed on the substrate using the sputtering apparatus is improved.

The invention is not limited to the above-described embodiment, and various modifications and changes can be made without departing from the scope of the invention.

The entire disclosure of Japanese Patent Application No. 2006-030609, filed Feb. 8, 2006, is expressly incorporated by reference herein.

What is claimed is:

1. A sputtering apparatus comprising:
a first cover made of a conductive material and having a first opening through which sputtered particles from a target are released;
a second cover made of a conductive material and having a second opening through which the sputtered particles released from the first opening impinge on a substrate;
an O-ring made of an insulating material and having a hollow center portion, the O-ring being disposed between the first cover and the second cover, with the hollow center portion disposed at the first opening and the second opening so that the first opening and the second opening communicate with each other via the hollow center portion;
a third cover placed over a face of at least one of the first cover and the second cover facing the O-ring, the third cover being made of a conductive material; and
an insulating material between the third cover and the face of the at least one of the first cover and the second cover.

2. The sputtering apparatus according to claim 1, wherein the third cover has a first extension extending from the face to a corresponding inner periphery of the first opening or the second opening, the first extension being disposed via the insulating material.

3. The sputtering apparatus according to claim 1, wherein the third cover has a second extension extending from the face to a corresponding outer periphery of the first cover or the second cover, the second extension being disposed via the insulating material.

4. The sputtering apparatus according to claim 1, wherein the third cover is an anti-adhesion plate having an irregular surface.
